(19) United States
(12) Patent Application Publication
(10) Pub. No.: US 2026/0223410 A1
(43) Pub. Date: Jul. 30, 2026

(54) SEMICONDUCTOR DEVICE AND DISPLAY PANEL

(71) Applicant: Guangzhou China Star Optoelectronics Semiconductor Display Technology Co., Ltd., Guangzhou (CN)

(72) Inventors: Shan LI, Guangzhou (CN); Juncheng XIAO, Guangzhou (CN); Jun ZHAO, Guangzhou (CN); Weiran CAO, Guangzhou (CN); Mingjiue YU, Guangzhou (CN); Xiaoxing ZHANG, Guangzhou (CN)

(73) Assignee: Guangzhou China Star Optoelectronics Semiconductor Display Technology Co., Ltd., Guangzhou (CN)

(21) Appl. No.: 19/253,859

(22) Filed: Jun. 29, 2025

(30) Foreign Application Priority Data
Jan. 24, 2025 (CN) 202510122793.2

(51) Int. Cl. H10D 30/67

(52) U.S. Cl. CPC H10D 30/6755

(57) ABSTRACT

A semiconductor device and a display panel are provided. The semiconductor device comprises an active layer comprising a first semiconductor layer, and the first semiconductor layer comprises an N-type metal oxide semiconductor material, and a first doping element and/or a second doping element doped in the N-type metal oxide semiconductor material. The first doping element is a metal element and an oxide of the first doping element is a P-type semiconductor material; and a bond energy of a chemical bond between the second doping element and an oxygen atom greater than a bond energy of a chemical bond between at least a part of metal elements in the N-type metal oxide semiconductor material and the oxygen atom.

### CROSS REFERENCE TO RELATED APPLICATIONS

This application claim priority to the Chinese patent application No. 202510122793.2, filed on Jan. 24, 2025, the entire contents of which are incorporated herein by reference.

### TECHNICAL FIELD

The present disclosure relates to the field of display technologies, and more particularly, to semiconductor manufacturing technologies, and more particularly, to a semiconductor device and a display panel.

### BACKGROUND

Oxide semiconductor thin film transistors have attracted wide attention due to their high electron mobility, excellent uniformity, good transparency, low cost, and the like. At present, indium gallium zinc oxide (IGZO) semiconductor materials have been in mass production. Various research institutes are working to develop other oxide semiconductor materials having high mobility as an alternative formulation for future IGZO materials. Generally, a thin film transistor having high mobility is obtained using an oxide semiconductor having a high electron concentration by common methods including: increasing the content of indium (In) elements in the oxide semiconductor, or adding other materials (such as Sn) that can provide more electrons in the oxide semiconductor target.

The sub-threshold swing (SS) value of a thin film transistor device affects a current ramp rate (dI/dV, indicating a physical value that represents the change in current per unit voltage). For a liquid crystal display (LCD) product, a low sub-threshold swing of the thin film transistor device may cause high current ramp rate, so that the operating range of the gate high potential (Vgate-high, Vgh) to gate low potential (Vgate-low, Vgl) of the thin film transistor device is reduced. For an organic light-emitting diode (OLED) product, a low sub-threshold swing of the thin film transistor device therein may cause high current ramp, so that the corresponding brightness gradient changes little, which is unfavorable to gray-scale switching.

Therefore, there is a need to increase the sub-threshold swing of the thin film transistor device to solve the above problems caused by the low sub-threshold swing.

### SUMMARY

Embodiments of the present disclosure provide a semiconductor device and a display panel, which can improve the sub-threshold swing of the semiconductor device to solve the problems caused by a low sub-threshold swing.

According to a first aspect of the present disclosure, a semiconductor device including an active layer is provided. The active layer includes a first semiconductor layer, and the first semiconductor layer includes an N-type metal oxide semiconductor material, and a first doping element and/or a second doping element doped in the N-type metal oxide semiconductor material.

The first doping element is a metal element and an oxide of the first doping element is a P-type semiconductor material, and a bond energy of a chemical bond formed between the second doping element and an oxygen atom is greater than a bond energy of a chemical bond between at least a part of metal elements in the N-type metal oxide semiconductor material and an oxygen atom.

In some embodiments, a number of defect states in the N-type metal oxide semiconductor material is proportional to an increase of the first doping element.

In some embodiments, the first doping element is a metal oxide and the oxide of the first doping element is a P-type semiconductor material.

In some embodiments, the first doping element includes a copper element.

In some embodiments, in the first semiconductor layer, a molar ratio of the copper element is greater than or equal to 0.1% and less than or equal to 10%.

In some embodiments, the second doping element includes at least one of a silicon element, a boron element, a tantalum element, a niobium element, a cadmium element, or a lanthanide element.

In some embodiments, the N-type metal oxide semiconductor material includes at least one of indium gallium zinc tin oxide, indium gallium oxide, indium gallium zinc oxide, or lanthanide-doped indium tin oxide.

In some embodiments, a sub-threshold swing of the first semiconductor layer is greater than or equal to 0.4 V/dec and less than or equal to 1.0 V/dec.

In some embodiments, a carrier concentration of the first semiconductor layer is greater than or equal to 1E14 cm⁻³ and less than or equal to 5E19 cm⁻³.

In some embodiments, a resistance of the first semiconductor layer is greater than or equal to 1E4 Ω/□ and less than or equal to 1E10 Ω/□.

In some embodiments, a Hall mobility of the first semiconductor layer is greater than or equal to 30 cm²/(V·s) and less than or equal to 70 cm²/(V·s).

In some embodiments, the active layer includes one or more second semiconductor layers laminated with the first semiconductor layer, and the one or more second semiconductor layers include a metal oxide semiconductor material.

In some embodiments, a Hall mobility of the one or more second semiconductor layers is lower than a Hall mobility of the first semiconductor layer.

In some embodiments, the metal oxide semiconductor material includes indium gallium zinc oxide.

In some embodiments, the active layer includes at least two second semiconductor layers, and the first semiconductor layer is disposed between two of the second semiconductor layers.

In some embodiments, the semiconductor device further includes a gate, a source, and a drain. The gate is disposed opposite to the active layer, and the source and the drain are disposed on a side of the active layer away from the gate and are respectively electrically connected to opposite ends of the active layer.

The semiconductor device includes any one of a top gate self-aligned thin film transistor, a back channel etch type thin film transistor, and an etch stop type thin film transistor.

According to a second aspect of the present disclosure, there is provided a display panel including the semiconductor device described above.

Other features and advantages of the present disclosure will be described in detail in the detailed description that follows.

### BRIEF DESCRIPTION OF THE DRAWINGS

In order to make the embodiments of the present disclosure clear, the drawings use for illustrating the embodiments are described below. It is apparent that the drawings in the following description are merely some embodiments of the present disclosure, and other drawings may be obtained by those skilled in the art based on these drawings without involving any inventive effort.

For a full understanding of the present disclosure and its advantages, the following description will be made with reference to the accompanying drawings, in which same or similar reference numerals designate same or similar parts in the following description.

FIG. 1 is a schematic cross-sectional view of a structure of a semiconductor device according to some embodiments of the present disclosure.

FIG. 2 is a schematic cross-sectional view of a structure of an active layer according to some embodiments of the present disclosure.

FIG. 3 is a schematic cross-sectional view of another structure of an active layer according to some embodiments of the present disclosure.

FIG. 4 is a schematic cross-sectional view of another structure of an active layer according to some embodiments of the present disclosure.

FIG. 5 is a schematic cross-sectional view of another structure of a semiconductor device according to some embodiments of the present disclosure.

FIG. 6 is a schematic cross-sectional view of another structure of a semiconductor device according to some embodiments of the present disclosure.

### LIST OF REFERENCE NUMERALS

1(1′ or 1″). Semiconductor device; 2. Active layer; 3. First semiconductor layer; 4. Second semiconductor layer; 5. Gate; 6. Gate insulating layer; 7. Source; 8. Drain; 9. Substrate; 10. Passivation layer; 11. Light-shielding layer; 12. Barrier layer; 13. Interlayer insulating layer; 14. Etch stop layer.

### DETAILED DESCRIPTION

The technical solutions in the embodiments of the present disclosure will be described below in conjunction with the accompanying drawings.

For a liquid crystal display (LCD) product, a low sub-threshold swing of the thin film transistor device therein may cause high current ramp, which will reduce the operating range of the gate high potential (Vgh) to gate low potential (Vgl) of the thin film transistor device. For an organic light-emitting diode (OLED) product, a low sub-threshold swing of the thin film transistor device therein may cause high current ramp, so that the corresponding brightness gradient changes less, which is unfavorable to gray-scale switching.

The sub-threshold swing (SS) value of the metal oxide type thin film transistor device is generally increased via various processes including, for example, adding indium oxide into the active layer of the thin film transistor device, or selecting aluminum oxide (Al₂O₃) as the material of the passivation layer. However, after the active layer of the semiconductor device is formed, because the In—O bond energy is the lowest, high-energy particles (such as argon) may break the In—O bond in the active layer during the Al₂O₃ sputtering process, resulting in an increase in the concentration of the In element, a negative bias of the threshold voltage Vth of the thin film transistor device, and an increase in the value of the sub-threshold swing (SS). It was found through testing that the threshold voltage Vth of the thin film transistor device was 7.7V and the sub-threshold swing (SS) value was 0.28V/dec before the passivation layer made of Al₂O₃ was formed, and the threshold voltage Vth of the thin film transistor device was reduced to 1.8 V and the sub-threshold swing (SS) value was increased to 0.91V/dec after the passivation layer made of Al₂O₃ was formed.

Embodiments of the present disclosure provide solutions for increasing the sub-threshold swing (SS) value of the semiconductor device. Unlike the above-described solutions, the active layer made of a metal oxide semiconductor material according to the embodiments of the present disclosure is directly doped with a special doping element, so that a semiconductor characteristic of the active layer is reduced, thereby increasing the sub-threshold swing (SS) value of the semiconductor device, avoiding an excessively high current change rate, increasing the operating range of the gate high potential (Vgh) to gate low potential (Vgl) of the semiconductor device in an LCD product, and increasing the brightness gradient change in an OLED product, thereby improving the gray-scale switching effect. Reference is made in particular to the following description of several embodiments.

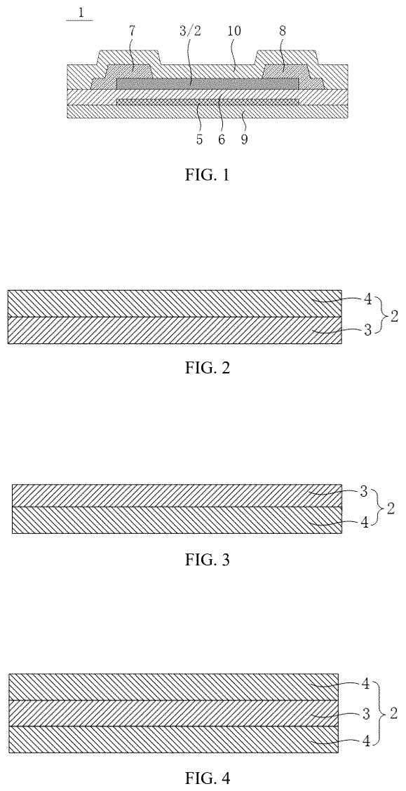

Referring to FIG. 1, some embodiments of the present disclosure provide a semiconductor device 1 including an active layer 2. The active layer 2 includes a first semiconductor layer 3. The first semiconductor layer 3 comprises an N-type metal oxide semiconductor material, and a first doping element and/or a second doping element doped in the N-type metal oxide semiconductor material. The first doping element is a metal element, and the oxide of the first doping element is a P-type semiconductor material. The second doping element, together with an oxygen atom, may form a chemical bond having a bond energy greater than that of the chemical bond between at least part of the metal elements in the N-type metal oxide semiconductor material and the oxygen atom.

In some embodiments, a number of the defect states in the N-type metal oxide semiconductor material increases with the addition of the first doping element, and the sub-threshold swing (SS) of the semiconductor device 1 increases with the addition of the first doping element and/or the second doping element.

In some embodiments, the semiconductor device 1 is a thin film transistor, which is not limited thereto.

It is to be understood that the carriers in the N-type metal oxide semiconductor material are electrons. According to the embodiments of the present disclosure, the first semiconductor layer 3 of the active layer 2 is formed by doping the N-type metal oxide semiconductor material with the first doping element and/or the second doping element.

Since the host material of the first semiconductor layer 3 of the active layer 2 is the type metal oxide semiconductor material and the oxide of the first doping element is the P-type semiconductor material, the doping of the N-type metal oxide semiconductor material with the first doping element has the function of suppressing the carriers in the N-type semiconductor, the N-type semiconductor characteristics of the first semiconductor layer 3 can be reduced, and the sub-threshold swing of the semiconductor device 1 can be increased. Moreover, the doping of the N-type metal oxide semiconductor material with the first doping element can introduce new defect states, thereby facilitating the reduction of the N-type semiconductor characteristics of the active layer 2. The sub-threshold swing of the semiconductor device 1 can be improved. Further, since the bond energy of the chemical bond between the second doping element and the oxygen atom is larger than the bond energy of the chemical bond between at least a part of the metal elements in the N-type metal oxide semiconductor material and the oxygen atom, the doping of the N-type metal oxide semiconductor material with the second doping element can increase the content of the metal element in the N-type metal oxide semiconductor material, thereby increasing the sub-threshold swing of the semiconductor device 1.

Therefore, according to the embodiments of the present disclosure, the sub-threshold swing of the semiconductor device 1 can be increased by doping the N-type metal oxide semiconductor material with the first doping element and/or the second doping element. When the semiconductor device 1 is applied to the LCD product, the operating range of the gate high potential (Vgh) to the gate low potential (Vgl) of the semiconductor device 1 can be increased. When the semiconductor device 1 is applied to the OLED product, the brightness gradient change can be increased, thereby improving the gray-scale switching effect.

In some embodiments, the first doping element includes a copper element, and the copper oxide is the P-type semiconductor material.

In some embodiments, the molar ratio of the copper element in the first semiconductor layer 3 is greater than or equal to 0.1% and less than or equal to 10%. It is to be understood that the doping concentration is also an important factor affecting the sub-threshold swing of the semiconductor device 1, and that variations in the doping concentration directly affect the conductivity of the active layer 2, thereby affecting the sub-threshold swing of the semiconductor device 1. Therefore, in designing and fabricating the semiconductor device 1, it is suggested to accurately control the doping concentration so as to achieve optimal sub-threshold swing performance. For a copper element, by controlling the molar ratio of the copper element in the range of 0.1% to 10%, the sub-threshold swing of the semiconductor device 1 can be increased while ensuring that the semiconductor device 1 has a high mobility.

In some embodiments, the molar ratio of the copper element in the first semiconductor layer 3 is 0.1%, 0.2%, 0.4%, 0.6%, 0.8%, 1%, 2%, 3%, 4%, 5%, 6%, 7%, 8%, 9% or 10%, which is not limited thereto.

In some embodiments, the second doping element includes at least one of silicon, boron, tantalum, niobium, cadmium, or lanthanide.

In some embodiments, the second doping element includes at least one of silicon, boron, tantalum, niobium, or cadmium.

In some embodiments, the N-type metal oxide semiconductor material of the first semiconductor layer 3 is doped with only the first doping element. For example, copper is added into the N-type metal oxide semiconductor material of the first semiconductor layer 3.

In other embodiments, the N-type metal oxide semiconductor material of the first semiconductor layer 3 is doped with only the second doping element. For example, at least one of silicon, boron, tantalum, niobium, cadmium, or lanthanide is added into the N-type metal oxide semiconductor material of the first semiconductor layer 3.

In other embodiments, the N-type metal oxide semiconductor material of the first semiconductor layer 3 is doped with the first doping element and the second doping element, For example, the N-type metal oxide semiconductor material of the first semiconductor layer 3 is doped with copper and at least one of the above-listed second doping element.

In some embodiments, the N-type metal oxide semiconductor material comprises indium (In).

In some embodiments, the N-type metal oxide semiconductor material includes at least one of indium gallium zinc tin oxide (IGZTO), indium gallium oxide (IGO), indium gallium zinc oxide (IGZO), or lanthanide-doped indium tin oxide (Ln-IZO).

It is to be understood that the N-type metal oxide semiconductor material in the first semiconductor may be a conventional metal oxide target material, which is not limited thereto.

In some embodiments, the first semiconductor layer 3 has the sub-threshold swing greater than or equal to 0.4 V/dec and less than or equal to 1.0 V/dec.

It is to be noted that a conventional semiconductor device that is not doped with the first doping element and/or the second doping element has a sub-threshold swing in the range of 0.1 V/dec to 0.4 V/dec. The sub-threshold swing of the semiconductor device 1 provided in the embodiments of the present disclosure can be effectively improved by doping with the first doping element and/or the second doping element.

In some embodiments, the carrier concentration of the first semiconductor layer 3 is greater than or equal to 1E14 cm⁻3 and less than or equal to 5E19 cm⁻³.

It is to be noted that 1E14 cm⁻³ refers to 1*10¹⁴ cm⁻³ and 5E19 cm⁻³ refers to 5*10¹⁹cm⁻³.

It is to be understood that when the carrier concentration of a film layer is too high, for example, in the range of 1E20 cm⁻³ to 1E21 cm⁻³, the film layer has a conductor characteristic. Although the first semiconductor layer 3 is doped with the first doping element and/or the second doping element, the semiconductor characteristics of the first semiconductor layer 3 are maintained.

In some embodiments, the resistance of the first semiconductor layer 3 is greater than or equal to 1E4 Ω/□ and less than or equal to 1E10 Ω/□.

It is to be noted that the resistance mentioned above refers to a sheet resistance, that is, a resistance value per unit area. For example, 1E4 Ω/□ refers to 1*10⁴Ω/m², and 1E10 Ω/□ refers to 1*10¹⁰Ω/m².

It is to be understood that when the resistance of a film layer is low, the film layer has a conductor characteristic. The resistance of the first semiconductor layer 3 provided in the present embodiments is in the range of 1E4 Ω/□ to 1E10 Ω/□, indicating that the first semiconductor layer 3 has a semiconductor characteristic.

In some embodiments, the Hall mobility of the first semiconductor layer 3 is greater than or equal to 30cm² /(V·s) and less than or equal to 70cm² /(V·s).

It is to be understood that when the Hall mobility of a film layer is too high, for example, greater than 100cm² /(V·s), the film layer has a conductor characteristic. The Hall mobility of the first semiconductor layer 3 provided in the present embodiments is within 30 cm²/(V·s) to 70 cm² /(V·s), indicating that the first semiconductor layer 3 has a semiconductor characteristic.

Generally, the Hall mobility of an indium-gallium-zinc oxide (IGZO) semiconductor layer is only 10 cm²/(V·s). It is clear that the Hall mobility of the first semiconductor layer 3 provided in the present embodiments is much larger than that of the IGZO semiconductor layer, which shows that the semiconductor device 1 provided in the present embodiments has a high mobility.

In some embodiments, the active layer 2 is a monolayer structure. That is, the active layer 2 only consists of the first semiconductor layer 3.

In other embodiments, the active layer 2 may be a multilayer structure. For example, the active layer 2 has a two-layer or three-layer structure, which is not limited thereto. When the active layer 2 is a multilayer structure, the materials of any two adjacent semiconductor layers are different.

In some embodiments, as shown in FIGS. 2 to 4, the active layer 2 further includes a second semiconductor layer 4 laminated with the first semiconductor layer 3. The second semiconductor layer 4 comprises a metal oxide semiconductor material.

It is to be understood that the second semiconductor layer 4 is also an N-type semiconductor.

In some embodiments, the Hall mobility of the second semiconductor layer 4 is less than the Hall mobility of the first semiconductor layer 3.

It is to be understood that since the mobility of the first semiconductor layer 3 is greater than the mobility of the second semiconductor layer 4, the combination of the two layers in the active layer 2 advantageously improves the overall mobility of the active layer 2.

In some embodiments, as shown in FIGS. 2 and 3, the active layer 2 includes the first semiconductor layer 3 and the second semiconductor layer 4 disposed on a side of the first semiconductor layer 3, and the second semiconductor layer 4 comprises a metal oxide semiconductor material. In this case, the active layer 2 has a two-layer structure.

In another embodiment, as shown in FIG. 4, the active layer 2 includes at least two second semiconductor layers 4, and the first semiconductor layer 3 is disposed between the two second semiconductor layers 4. Each of the second semiconductor layers 4 comprises a metal oxide semiconductor material. In this case, the active layer 2 has a three-layer structure.

In some embodiments, the thickness of the first semiconductor layer 3 of the active layer 2 in a three-layer structure is less than the thickness of the first semiconductor layer 3 of the active layer 2 in a two-layer structure.

In the embodiments of the present disclosure, the active layer 2 is provided in a multi-layer structure. On the one hand, by providing at least one of a plurality of layers in the multi-layer structure as the first semiconductor layer 3 having a higher mobility and a larger sub-threshold swing, it is advantageous to reduce the overall thickness of the active layer 2 while improving the overall mobility and the sub-threshold swing of the semiconductor device 1, so that negative bias of the threshold voltage Vth due to the excessive thickness of the active layer 2 can be avoided, thereby improving the stability of the semiconductor device 1. On the other hand, when the second semiconductor layer 4, which has a relatively low mobility in the active layer 2, is in contact with the other film layers, the defects of the contact interface between the active layer 2 and the adjacent film layers can be reduced, and the stability and reliability of the semiconductor device 1 can be improved.

In some embodiments, the metal oxide semiconductor material includes indium gallium zinc oxide (IGZO).

Since IGZO has been mass produced, and IGZO can improve the defects of the contact interface, the application of IGZO in combination with the first semiconductor layer 3 in the active layer 2 can improve the stability and reliability of the semiconductor device 1 while improving the mobility and the sub-threshold swing of the semiconductor device 1.

In some embodiments, the semiconductor device 1 further includes a gate 5, a gate insulating layer 6, a source 7 and a drain 8. The gate 5 is disposed on a side of the active layer 2 and is disposed opposite to the active layer 2. The gate insulating layer 6 is disposed at least between the gate 5 and the active layer 2. The source 7 and the drain 8 are disposed on a side of the active layer 2 and are electrically connected to opposite ends of the active layer 2, respectively.

In some embodiments, as shown in FIG. 1, the semiconductor device 1 further includes a substrate 9 and a passivation layer 10. The gate 5 is disposed on the substrate 9, and the gate insulating layer 6 covers the substrate 9 and the gate 5. The active layer 2 is disposed on the gate insulating layer 6, and the active layer 2 is disposed opposite the gate 5. The source 7 and the drain 8 are disposed on opposite ends of the active layer 2, respectively. The passivation layer 10 covers the gate insulating layer 6, the source 7, the drain 8 and a part of the active layer 2.

In some embodiments, the material of the gate insulating layer 6 and the passivation layer 10 is selected from at least one of a silicon oxide, a silicon nitride, or a silicon nitride oxide, which is not limited thereto.

It is to be understood that the semiconductor device 1 provided in the embodiments of the present disclosure is a back channel etch (BCE)-type thin film transistor. The gate 5 underneath the active layer 2 can serve as a light shield used to avoid the provision of an additional light shielding layer 11 underneath the active layer 2, thereby simplifying the structure of the semiconductor device 1.

Since only the material of the active layer 2 is modified in the embodiments of the present disclosure, the semiconductor device 1 provided in the embodiments of the present disclosure can be produced using a production line which has been produced in mass. In the process of preparing the active layer 2, the first doping element and/or the second doping element may be directly added to a raw material of the metal oxide conductor material target, and after sintering, a metal oxide target containing the uniformly mixed first doping element and/or second doping element is obtained. After the active layer 2 is formed by the metal oxide target material containing the first doping element and/or the second doping element, an additional doping process is not required, so that the manufacturing process of the active layer 2 is simplified, the manufacturing efficiency of the active layer 2 is improved, and the manufacturing cost of the active layer 2 is reduced.

When the active layer 2 is a two-layer structure, the second semiconductor layer 4 may be provided between the first semiconductor layer 3 and the passivation layer 10, or between the first semiconductor layer 3 and the gate insulating layer 6. When the second semiconductor layer 4 is disposed between the first semiconductor layer 3 and the passivation layer 10, the defects of the contact interface between the active layer 2 and the passivation layer 10 can be reduced. When the second semiconductor layer 4 is provided between the first semiconductor layer 3 and the gate insulating layer 6, the defects of the contact interface between the active layer 2 and the gate insulating layer 6 can be reduced, so that the stability and reliability of the semiconductor device 1 can be improved.

When the active layer 2 is a three-layer structure, one of the second semiconductor layers 4 is provided between the first semiconductor layer 3 and the passivation layer 10, and the other of the second semiconductor layers 4 is provided between the first semiconductor layer 3 and the gate insulating layer 6. In this case, the defects of the contact interfaces between the active layer 2 and the passivation layer 10 and between the active layer 2 and the gate insulating layer 6 can be simultaneously reduced, thereby further improving the stability and reliability of the thin film transistor.

In the embodiments of the present disclosure, the first semiconductor layer 3 of the active layer 2 is formed by doping the N-type metal oxide semiconductor material with the first doping element and/or the second doping element. Since the doping of the N-type metal oxide semiconductor material with the first doping element can introduce a new defect states, it is advantageous to reduce the N-type semiconductor characteristic of the active layer 2, and therefore the sub-threshold swing of the semiconductor device 1 can be improved. Further, since the bond energy of the chemical bond between the second doping element and the oxygen atom is larger than the bond energy of the chemical bond between at least a part of the metal element in the N-type metal oxide semiconductor material and the oxygen atom, the doping of the N-type metal oxide semiconductor material with the second doping element can increase the content of the metal element in the N-type metal oxide semiconductor material, thereby increasing the sub-threshold swing of the semiconductor device 1. Therefore, according to the embodiments of the present disclosure, the sub-threshold swing of the semiconductor device 1 can be increased by incorporating the first doping element and/or the second doping element in the N-type metal oxide semiconductor material. When the semiconductor device 1 is applied to the LCD product, the operating range of the Vgh to Vgl of the semiconductor device 1 can be increased. And when the semiconductor device 1 is applied to an OLED product, the brightness gradient change can be increased, thereby improving the gray-scale switching effect.

As shown in FIG. 5, some embodiments of the present disclosure further provide another semiconductor device 1′, which is different from the semiconductor device 1 provided in the foregoing embodiments in that the semiconductor device 1′ in the present embodiments of the present disclosure is a top-gate self-aligned type thin film transistor. The semiconductor device 1′ further includes a light shielding layer 11, a barrier layer 12, and an interlayer insulating layer 13. The light shielding layer 11 is disposed on the substrate 9, and the barrier layer 12 covers the substrate 9 and the light shielding layer 11. The active layer 2 is disposed on the barrier layer 12 and is disposed opposite to the light shielding layer 11. The gate insulating layer 6 and the gate 5 are stacked on the active layer 2 in sequence, and a side of the gate insulating layer 6 far away from the active layer 2 has the same shape and area as a side of the gate 5 adjacent to the active layer 2. The interlayer insulating layer 13 covers the barrier layer 12, the active layer 2, the gate insulating layer 6, and the gate 5. The source 7 and the drain 8 are provided on the interlayer insulating layer 13, and are electrically connected to the active layer 2 via the through-holes passing through the interlayer insulating layer 13. The passivation layer 10 covers the interlayer insulating layer 13, the source 7 and the drain 8.

In some embodiments, the material of the interlayer insulating layer 13 is selected from, but not limited to, at least one of a silicon oxide, a silicon nitride, or a silicon nitride oxide.

The active layer 2 in the present embodiments of the present disclosure may also be prepared in the same manner as in the above embodiments, and details are not described herein.

When the active layer 2 is a two-layer structure, the second semiconductor layer 4 may be disposed between the first semiconductor layer 3 and the gate insulating layer 6 (and the interlayer insulating layer 13), or between the first semiconductor layer 3 and the barrier layer 12. When the second semiconductor layer 4 is disposed between the first semiconductor layer 3 and the gate insulating layer 6 (and the interlayer insulating layer 13), the defects in the contact interface between the active layer 2 and the gate insulating layer 6 (and the interlayer insulating layer 13) can be reduced. When the second semiconductor layer 4 is disposed between the first semiconductor layer 3 and the barrier layer 12, the defects of the contact interface between the active layer 2 and the barrier layer 12 can be reduced. In this case, the stability and reliability of the semiconductor device 1′ can be improved.

When the active layer 2 is a three-layer structure, one of the second semiconductor layers 4 is disposed between the first semiconductor layer 3 and the gate insulating layer 6 (and the interlayer insulating layer 13), and the other of the second semiconductor layers 4 is disposed between the first semiconductor layer 3 and the barrier layer 12. In this case, the defects of the contact interfaces between the active layer 2 and the gate insulating layer 6 (and the interlayer insulating layer 13), and between the active layer 2 and the barrier layer 12 can be simultaneously reduced, thereby further improving the stability and reliability of the semiconductor device 1′.

In the embodiments of the present disclosure, the first semiconductor layer 3 of the active layer 2 is formed by adding the first doping element and/or the second doping element into the N-type metal oxide semiconductor material. The doping of the N-type metal oxide semiconductor material with the first doping element can introduce a new defect states, thereby facilitating the reduction of the N-type semiconductor characteristics of the active layer 2, and thus the sub-threshold swing of the semiconductor device 1′ can be improved. Also, since the bond energy of the chemical bond between the second doping element and the oxygen atom is larger than the bond energy of the chemical bond between at least a part of the metal elements in the N-type metal oxide semiconductor material and the oxygen atom, the doping of the N-type metal oxide semiconductor material with the second doping element can increase the content of the metal element in the N-type metal oxide semiconductor material, thereby increasing the sub-threshold swing of the semiconductor device 1′. Thus, according to the embodiments of the present disclosure, the sub-threshold swing of the semiconductor device 1′ may be increased by doping the N-type metal oxide semiconductor material with the first doping element and/or the second doping element. When the semiconductor device 1′ is applied to the LCD product, the operating range of the Vgh to Vgl of the semiconductor device 1′ can be increased, and when the semiconductor device 1 is applied to an OLED product, the brightness gradient change can be increased, thereby improving the gray-scale switching effect.

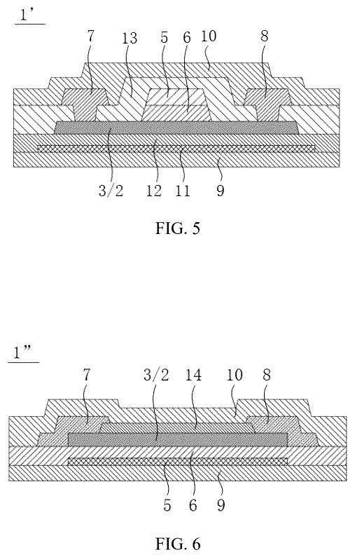

As shown in FIG. 6, some embodiments of the present disclosure further provide another semiconductor device 1″, which is different from the semiconductor device 1 provided in the above embodiments in that the semiconductor device 1″ in the present embodiments of the present disclosure is an etch stop layer (ESL) type thin film transistor. The semiconductor device 1″ further includes an etch stop layer 14. The etch stop layer 14 is disposed on the active layer 2 and corresponds to a channel region of the active layer 2. The source 7 and the drain 8 are disposed on opposite ends of the active layer 2 and cover two opposite ends of the etch stop layer 14, respectively. The passivation layer 10 covers the gate insulating layer 6, the source 7, the drain 8, and the etch stop layer 14.

In some embodiments, the material of the etch stop layer 14 is selected from, but not limited to, at least one of a silicon oxide, a silicon nitride, or a silicon nitride oxide.

In the same manner as in the above embodiments, the provision of the gate 5 below the active layer 2 can serve as a light shield, thereby avoiding the provision of an additional light shielding layer 11 below the active layer 2, thereby simplifying the structure of the thin film transistor.

The active layer 2 in the embodiments of the present disclosure may also be prepared in the same manner as in the above embodiment, and details are not described herein.

When the active layer 2 is a two-layer structure, the second semiconductor layer 4 may be disposed between the first semiconductor layer 3 and the etch stop layer 14, or between the first semiconductor layer 3 and the gate insulating layer 6. When the second semiconductor layer 4 is disposed between the first semiconductor layer 3 and the etch stop layer 14, defects of the contact interface between the active layer 2 and the etch stop layer 14 can be reduced. When the second semiconductor layer 4 is disposed between the first semiconductor layer 3 and the gate insulating layer 6, defects in the contact interface between the active layer 2 and the gate insulating layer 6 can be reduced. In this case, the stability and reliability of the semiconductor device 1″ can be improved.

When the active layer 2 is a three-layer structure, one of the second semiconductor layers 4 is disposed between the first semiconductor layer 3 and the etch stop layer 14, and the other of the second semiconductor layers 4 is disposed between the first semiconductor layer 3 and the gate insulating layer 6. In this case, the defects of the contact interface between the active layer 2 and the etch stop layer 14 and the gate insulating layer 6 can be simultaneously reduced, thereby further improving the stability and reliability of the semiconductor device 1″.

According to the embodiments of the present disclosure, the first semiconductor layer 3 of the active layer 2 is formed by adding the first doping element and/or the second doping element in the N-type metal oxide semiconductor material. The adding of the first doping element in the N-type metal oxide semiconductor material can introduce a new defect states, thereby facilitating the reduction of the N-type semiconductor characteristics of the active layer 2, and thus the sub-threshold swing of the semiconductor device 1″ can be increased. Also, since the bond energy of the chemical bond between the second doping element and the oxygen atom is larger than the bond energy of the chemical bond between at least a part of the metal elements in the N-type metal oxide semiconductor material and the oxygen atom, adding the second doping element in the N-type metal oxide semiconductor material can increase the content of the metal elements in the N-type metal oxide semiconductor material, thereby increasing the sub-threshold swing of the semiconductor device 1″. Thus, the sub-threshold swing of the semiconductor device 1″ according to the embodiments of the present disclosure may be increased by adding the first doping element and/or the second doping element in the N-type metal oxide semiconductor material. When the semiconductor device 1″ is applied to the LCD product, the operating range of Vgh to Vgl of the semiconductor device 1″ can be increased, and when the semiconductor device 1″ is applied to the OLED product, the brightness gradient change can be increased, thereby improving the gray-scale switching effect.

Some embodiments of the present disclosure further provide a display panel including the semiconductor device provided in any one of the above embodiments. The specific type of the display panel is not limited in the embodiments of the present disclosure.

In some embodiments, the display panel includes an array substrate in which the semiconductor device is disposed, which is not limited thereto.

In some embodiments, the display panel is a liquid crystal display panel including a gate driven on array (GOA) driver circuit. The GOA driver circuit includes the semiconductor devices described in at least one of the foregoing embodiments. Since the semiconductor device has a large sub-threshold swing, the current ramp rate can be reduced, so that the operating range of Vgh to Vgl of the semiconductor device can be increased, and the margin of the GOA circuit can be increased.

In another embodiment, the display panel is an OLED display panel including a drive circuit. The driver circuit includes the semiconductor device described in at least one of the foregoing embodiments. Since the semiconductor device has a large sub-threshold swing, the current ramp rate can be reduced, so that the brightness gradient change can be increased, and the gray-scale switching effect can be improved.

In the embodiments of the present disclosure, since the semiconductor device has a high mobility, it is advantageous to improve the response speed, the working efficiency and the stability of the display panel. The power consumption of the display panel can be reduced. Moreover, since the sub-threshold swing of the semiconductor device is increased, when the semiconductor device is applied to the LCD product, the operating range of Vgh to Vgl of the semiconductor device can be increased, and when the semiconductor device is applied to the OLED product, the brightness gradient change can be increased, thereby improving the gray-scale switching effect.

In the semiconductor device and the display panel according to of the embodiment of the present disclosure, the first semiconductor layer of the active layer is formed by adding the first doping element and/or the second doping element in the N-type metal oxide semiconductor material. Since the first doping element is the metal element and the oxide of the first doping element is the P-type semiconductor material, adding the first doping element in the N-type metal oxide semiconductor material has the effect of suppressing the carriers of the N-type semiconductor, thereby reducing the N-type semiconductor characteristics of the active layer and further improving the sub-threshold swing of the semiconductor device. Further, since the bond energy of the chemical bond between the second doping element and the oxygen atom is larger than the bond energy of the chemical bond between at least a part of the metal elements in the N-type metal oxide semiconductor material and the oxygen atom, adding the second doping element in the N-type metal oxide semiconductor material can increase the content of the metal elements in the N-type metal oxide semiconductor material, thereby increasing the sub-threshold swing of the semiconductor device. Thus, the embodiments of the present disclosure can increase the sub-threshold swing of the semiconductor device by adding the first doping element and/or the second doping element in the N-type metal oxide semiconductor material. When the semiconductor device is applied to the LCD product, the operating range of Vgh to Vgl of the semiconductor device can be increased, and when the semiconductor device is applied to the OLED product, the brightness gradient change can be increased, thereby improving the gray-scale switching effect.

In the description of the present application, the terms “first” and “second” are used for descriptive purposes only and are not to be construed as indicating or implying relative importance or implying the number of indicated technical features. Therefore, the features defined as “first” or “second” may explicitly or implicitly include one or more features. In the description of the present disclosure, “plurality” means two or more, unless expressly and specifically defined otherwise.

In the above embodiments, the description of each embodiment has its own emphasis, and parts not described in detail in a certain embodiment may be referred to the related description of other embodiments. The embodiments, implementations, and related technical features of the present disclosure may be combined and replaced with each other without conflict.

In view of the above, the embodiments described above are only a part of embodiments of the present disclosure and not intended to limit the present disclosure in any form. Any simple changes, equivalent variations and modifications made to the above embodiments in accordance with the technical substance of the present disclosure, without departing from the technical solutions of the present disclosure, still fall within the scope of the present disclosure.

What is claimed is:

1. A semiconductor device comprising an active layer, wherein the active layer comprises a first semiconductor layer; and the first semiconductor layer comprises an N-type metal oxide semiconductor material, as well as a first doping element and/or a second doping element doped in the N-type metal oxide semiconductor material; wherein
the first doping element is a metal element and an oxide of the first doping element is a P-type semiconductor material; and a bond energy of a chemical bond formed between the second doping element and an oxygen atom is greater than a bond energy of a chemical bond between at least a part of metal elements in the N-type metal oxide semiconductor material and an oxygen atom.

2. The semiconductor device according to claim 1, wherein a number of defect states in the N-type metal oxide semiconductor material is proportional to an increase of the first doping element.

3. The semiconductor device according to claim 1, wherein the first doping element comprises a copper element.

4. The semiconductor device according to claim 3, wherein in the first semiconductor layer, a molar ratio of the copper element is greater than or equal to 0.1% and less than or equal to 10%.

5. The semiconductor device according to claim 1, wherein the second doping element comprises at least one of a silicon element, a boron element, a tantalum element, a niobium element, a cadmium element, or a lanthanide element.

6. The semiconductor device according to claim 1, wherein the N-type metal oxide semiconductor material comprises at least one of indium gallium zinc tin oxide, indium gallium oxide, indium gallium zinc oxide, or lanthanide-doped indium tin oxide.

7. The semiconductor device according to claim 1, wherein a sub-threshold swing of the first semiconductor layer is greater than or equal to 0.4 V/dec and less than or equal to 1.0 V/dec.

8. The semiconductor device according to claim 1, wherein a carrier concentration of the first semiconductor layer is greater than or equal to 1E14 cm⁻³ and less than or equal to 5E19 cm⁻³.

9. The semiconductor device according to claim 1, wherein a resistance of the first semiconductor layer is greater than or equal to 1E4 Ω/□ and less than or equal to 1E10 Ω/□.

10. The semiconductor device according to claim 1, wherein a Hall mobility of the first semiconductor layer is greater than or equal to 30 cm²/(V·s) and less than or equal to 70 cm²/(V·s).

11. The semiconductor device according to claim 1, wherein the active layer comprises one or more second semiconductor layers laminated with the first semiconductor layer, and the one or more second semiconductor layers comprise a metal oxide semiconductor material.

12. The semiconductor device according to claim 11, wherein a Hall mobility of the one or more second semiconductor layers is lower than a Hall mobility of the first semiconductor layer.

13. The semiconductor device according to claim 12, wherein the metal oxide semiconductor material comprises indium gallium zinc oxide.

14. The semiconductor device according to claim 11, wherein the active layer comprises at least two second semiconductor layers, and the first semiconductor layer is disposed between two second semiconductor layers of the second semiconductor layers.

15. The semiconductor device according to claim 14, wherein any adjacent two of the at least two second semiconductor layers are made of different materials.

16. The semiconductor device according to claim 1, further comprising a gate, a source, and a drain;
wherein the gate is disposed opposite to the active layer, and the source and the drain are disposed on a side of the active layer away from the gate and are respectively electrically connected to opposite ends of the active layer; and
the semiconductor device comprises any one of a top gate self-aligned thin film transistor, a back channel etch type thin film transistor, or an etch stop type thin film transistor.

17. The semiconductor device according to claim 16, wherein the gate is disposed above or under the active layer.

18. The semiconductor device according to claim 11, further comprising a gate, a source, and a drain;
wherein the gate is disposed opposite to the active layer, and the source and the drain are disposed on a side of the active layer away from the gate and are respectively electrically connected to opposite ends of the active layer; and
the semiconductor device comprises any one of a top gate self-aligned thin film transistor, a back channel etch type thin film transistor, or an etch stop type thin film transistor.

19. A display panel comprising a semiconductor device, wherein the semiconductor device comprises an active layer,
the active layer comprises a first semiconductor layer; and the first semiconductor layer comprises an N-type metal oxide semiconductor material, and a first doping element and/or a second doping element doped in the N-type metal oxide semiconductor material; wherein
the first doping element is a metal element and an oxide of the first doping element is a P-type semiconductor material, and a bond energy of a chemical bond formed between the second doping element and an oxygen atom is greater than a bond energy of a chemical bond between at least a part of metal elements in the N-type metal oxide semiconductor material and the oxygen atom.

20. The display panel according to claim 19, wherein the first doping element comprises a copper element, and the second doping element comprises at least one of a silicon element, a boron element, a tantalum element, a niobium element, a cadmium element, or a lanthanide element.
